(19) United States
(12) Patent Application Publication
(10) Pub. No.: US 2005/0083037 A1
(43) Pub. Date: Apr. 21, 2005

(54) Arrangement and method for testing substrates under load

(76) Inventors: Stefan Schneidewind, Reichenberg (DE); Claus Dietrich, Sacka (DE); Frank-Michael Werner, Dresden (DE); Don Feuerstein, Southbury, CT (US); Mike Lancaster, Williston, VT (US); Denis Place, Colchester, VT (US)

Correspondence Address: BAKER & BOTTS, 30 ROCKEFELLER PLAZA, NEW YORK, NY, 10112, US

(21) Appl. No.: 10/928,985

(22) Filed: Aug. 27, 2004

(30) Foreign Application Priority Data
Aug. 28, 2003 (DE) 103 40 066.4

(51) Int. Cl. G01R 31/02

(52) U.S. Cl. 324/158.1

(57) ABSTRACT

Arrangement and method for testing a substrate under load with a prober are provided, by which the full productivity of the prober can be exploited. The arrangement includes a chuck, a chuck driver, control electronics, probe or probe card holding means, and has a loading means for applying a thermal, mechanical, electrical or other physical or chemical loading to the substrate. The substrate is subjected to a loading and then its properties are measured by means of the prober. The loading means is arranged as a separate subassembly separated from the prober and therein is connected to the latter via a handling system. The method provides for the substrate to be brought into operative connection with a loading means, subjected to the loading in this loading means, then removed from the loading means and tested in terms of its functions.

### SPECIFICATION

This application claims priority from German Patent application Nos. DE 103 40 006.4 filed Aug. 28, 2003, which application is hereby incorporated by reference herein in its entirety.

### FIELD OF THE INVENTION

The invention relates to an arrangement for testing substrates under load, having a prober, at least comprising a chuck, a chuck driver, control electronics, probe or probe card holding means, and having loading means for applying a thermal, mechanical, electrical or other physical or chemical loading to the substrate. The invention also relates to a method of testing substrates under load, the substrate being subjected to a thermal, mechanical, electrical or another physical or chemical loading and the properties of the same being measured by means of a prober.

### BACKGROUND OF THE INVENTION

It is necessary to test substrates having electrical or electromechanical properties, such as semiconductor wafers, integrated circuits, multi-chip modules, printed circuit boards, flat displays and the like, during production. For this purpose, use is made of items of testing apparatus which make contact with the substrates via probes. These probes are used to apply test signals to the substrates and/or to measure a reaction of the substrates to the test signals.

In particular, such items of apparatus are used for testing substrates in the field of semiconductor production. Here, the designation “prober” will be found. In this case, as a rule integrated semiconductor chips are tested in their assembly on a semiconductor wafer, as it is known. Wafers are composed of various materials, such as silicon, GaAs, InP or comparable materials, and have a diameter of preferably 2″ to 12″ and a thickness of the order of magnitude of 90 to 500 μm. Following structuring of the wafers, the semiconductor chips that are produced as a result are tested and then the semiconductor chips are separated and then finally mounted to form finished components.

In order to ensure the quality of the finished integrated circuits, these must be tested individually with suitable programs. The reactions measured in the process to the test signals supply information about the quality of each individual circuit by means of a comparison with previously defined standards.

The testing in the wafer assembly, that is to say before separation, is advantageous since, following the separation, the individual chips would be difficult to handle for the testing and, expediently, testing could then be carried out again only after the final mounting. However, this would mean that a not inconsiderable number of chips which do not satisfy the quality requirements would be finally mounted.

Typically, the semiconductor wafers are stored and transported in wafer magazines. Here, as a rule up to 25 semiconductor wafers are held with a vertical spacing from one another in the wafer magazine.

The sensitivity of the semiconductor wafers with regard to fracture and any type of contamination forbid any contact with the human hand, for which reason handling robots are normally used, which transport the semiconductor wafers from one processing station to another or in or out of a wafer magazine.

Such a handling robot comprises a robot arm, which is attached to a robot drive and, as a result, can be moved in a vertical degree of freedom (z) and two horizontal degrees of freedom (x, y) and can be pivoted about a vertical axis of rotation. Arranged on the free front side of the robot arm is a wafer holder which has holding arms provided with vacuum suction holders. These holding arms are able to grip the semiconductor wafers and move them in or out of a processing station or wafer magazine, by the robot arm positioning its wafer holder directly under the underside or rear side of the semiconductor wafer by means of the robot drive and bringing it into contact. After that, the holding arm has vacuum applied to it, so that the semiconductor wafer is held by the vacuum openings on the upper side of the wafer holder and can be transported from one position to another.

Fully automatic test systems permit the operator or engineer to put in some wafer magazines and to operate with an initial setting, made once, until all the semiconductor wafers have been tested. A fully automatic test system of this type includes, in addition to the actual test arrangement, which substantially comprises chuck, chuck drive, control electronics, probe or probe card and appropriate holding and connecting means, a pattern recognition system for wafer self-adjustment, CCD camera or microscope for observing the test substrate, monitor, handling system, wafer magazine station and alignment station.

Probers are also used to test substrates under loading conditions. For this purpose, it is known for example to heat or to cool the chuck in order thus to measure the behavior of the substrates, in particular the semiconductor wafers, in the high-temperature or low-temperature range.

If loading measurements are required which are intended to take into account the effect of the loading over a loading time period, the prober is then blocked for further activities during such a loading measurement. The productivity of such a prober therefore decreases. One possibility of compensating for the reduced productivity during loading measurements over a loading period is represented by the use of a large number of probers, but this entails a costly requirement for space in the fabs and the cost disadvantage of the large number of devices.

It is therefore an object of the invention to specify an arrangement for testing substrates under load and a corresponding method by means of which the productivity of a prober can be utilized fully.

### SUMMARY OF THE INVENTION

The present invention provides an arrangement for testing substrates under load and a corresponding method by means of which the productivity of a prober can be utilized fully. A loading means is arranged as a separate subassembly separated from the prober and therein is connected to the latter via a handling system. Thus, in the loading means, the substrate can be subjected to particular physical or chemical states and the testing of the substrate can be performed at a suitable time following the action of the loading. Thus, the prober is not blocked during the application of the load. In this case, the handling system performs the transport of the substrate from the loading means to the prober, that is to say it removes the substrate from the loading means, places it on the chuck of the prober and removes it from the prober again after the testing operation, in order either to deposit it in the loading means again or to discharge it from the arrangement.

It is very frequently a case of positioning the substrate on the chuck in a manner aligned precisely in accordance with an intended position. Although the chuck has some possible displacements in the x, y and θ directions, with which compensation of an erroneous position can be carried out, firstly limits are placed on the possible displacement and, secondly, an error correction costs time, so that in a beneficial refinement of the arrangement according to the invention, the latter has an alignment station for the defined alignment of the substrate.

Since the handling between loading means and prober can be carried out largely automatically, a further refinement provides for the arrangement of a substrate magazine station. The substrate magazine which is used for the input and output of substrates can then be inserted into this substrate magazine station. In this case, the handling system takes the substrate from the substrate magazine, in order to supply it either to the loading means or to the prober and, at the end of the test operation, to supply it to the substrate magazine again.

In a refinement of the invention, provision is made for the loading means to be constructed as a temperature control station. In this temperature control station, the substrate can be subjected to a loading either of a temperature increased with respect to room temperature or of a low temperature. In this case, the substrate can remain in the temperature control station during a loading time, in order, for example, to establish the long-term influence of a high temperature on the serviceability of the substrate. Here, it is also possible for the temperature, controlled by a test program, to assume a temperature profile in order thus, for example, to simulate a temperature change as loading. During the loading time, the substrate can then be tested on the prober at regular intervals. Therefore, the prober is occupied only during these test times and not during the entire loading time.

During the testing itself, it is then likewise possible for temperature loading of the substrate to be carried out on the prober if, for example, the chuck is designed in a known way such that its temperature can be controlled.

It is beneficial if the temperature control station comprises a temperature chamber in which holding means for a plurality of substrates are provided. Therefore, a relatively large number of substrates can be subjected to the loading, which results in long loading times without great extra expenditure on devices.

In particular in order to load the substrate with a high temperature, it is expedient that the chamber can be closed in a substantially gastight manner and can be connected to an inert gas source. Thus, an inert gas atmosphere can be created within the chamber, which prevents thermal reaction of the substrate with its surroundings, for example in order that oxidation processes can be avoided.

In a further refinement of the invention, provision is made for the prober and the loading means to be arranged respectively in a module. As a result of such a modular structure, it is possible to expand the arrangement by further modules in a straightforward manner, for example to insert a plurality of loading means.

The individual modules can also be arranged in a cluster, which facilitates an embodiment of the invention in which each module has the same basic grid dimensions and each module can be connected to any other.

Easy adaptation of the structure of the cluster to the conditions of use is achieved by a module being designed to be mobile and locked in its erected position.

In a preferred way, the arrangement according to the invention is configured by the loading means and/or the prober being provided repeatedly, and being operatively connected to one another via one and the same handling system. This can be used, firstly, for the purpose of utilizing the prober or the probers well during a long loading time, but secondly also permit loading stations with mutually different types of loading to be provided, in order for example to simulate extreme temperature change or to test the influence of physical and chemical environmental parameters.

In a further refinement of the invention, provision is made for a common housing to be provided, into which the prober or probers, the loading means, the handling system and, if appropriate, the substrate magazine station and the alignment station are introduced. A housing of this type supports the structure in the form of a cluster. Advantageously associated with this is that, firstly, separate conditioning of the atmosphere within the housing can be performed. This is because, for example, if a plurality of temperature control stations are used within one cluster, under certain circumstances a considerable amount of waste heat is produced, which can be discharged separately in the housing and thus does not have to pass into the environment from which, under certain circumstances, it then has to be disposed of with considerable expenditure on air conditioning.

On the other hand, the common housing can be used for simple fixing of the individual models.

In a further refinement of the invention, provision is made for each module to be arranged on a vibration-insulating, preferably position-controlled, platform. Therefore, neither are vibrations transmitted from the surroundings to the modules nor are vibrations transmitted from the modules (for example in the case of mechanical loading modules) to the surroundings.

For the purpose of further decoupling of the individual modules from one another, this solution is developed further by each module being arranged on a separate platform from the other modules.

In order to create movement space for the handling system, which is used to optimize the movement lengths of the handling system, it is expedient that all the modules are arranged to form a central free space in the plan view, and the handling system and/or the alignment system are arranged in the central free space.

In numerous cases, it is necessary to subject semiconductor wafers to a loading test, for which reason the arrangement according to the invention can be configured by this being designed to test semiconductor wafers as substrates, that is to say all the components in the arrangement are designed for the handling, the alignment or the holding of semiconductor wafers.

On the side of the method, the object is achieved in that the substrate is brought into operative connection with a loading means, is subjected to the loading in this loading means, is then removed from the loading means and tested in terms of its functions. As opposed to the prior art, in which provision is merely made to subject the substrates to loading during the measurement, this method firstly permits the testing of the influence of loadings of many kinds and over a relatively long time period. Secondly, the prober is not blocked as a result of the application of a loading.

For the purpose of particularly rigorous loading testing or in order to simulate real load behavior, it is expedient that, during the loading, a loading program is executed in which the loading variables vary during a loading time period.

In a further variant of the method according to the invention, provision is made for the substrate to be repeatedly removed from the loading means and tested at time intervals during the loading time period. It is therefore, for example, possible to measure parameters of the substrate which have a time variance as a result of the loading.

### BRIEF DESCRIPTION OF THE DRAWINGS

Further features of the invention, its nature, and various advantages will be more apparent from the following detailed description of the preferred embodiments and the accompanying drawings, wherein like reference characters represent like elements throughout, and in which:

FIG. 1 shows a plan view of an apparatus according to the invention for testing semiconductor wafers, having a prober and a temperature control station;

FIG. 2 shows a plan view of an apparatus according to the invention for testing semiconductor wafers, having a prober and three temperature control stations;

FIG. 3 shows a plan view of an apparatus according to the invention for testing semiconductor wafers, having two probers and four temperature control stations; and

FIG. 4 shows a plan view of an apparatus according to the invention for testing semiconductor wafers in a production environment.

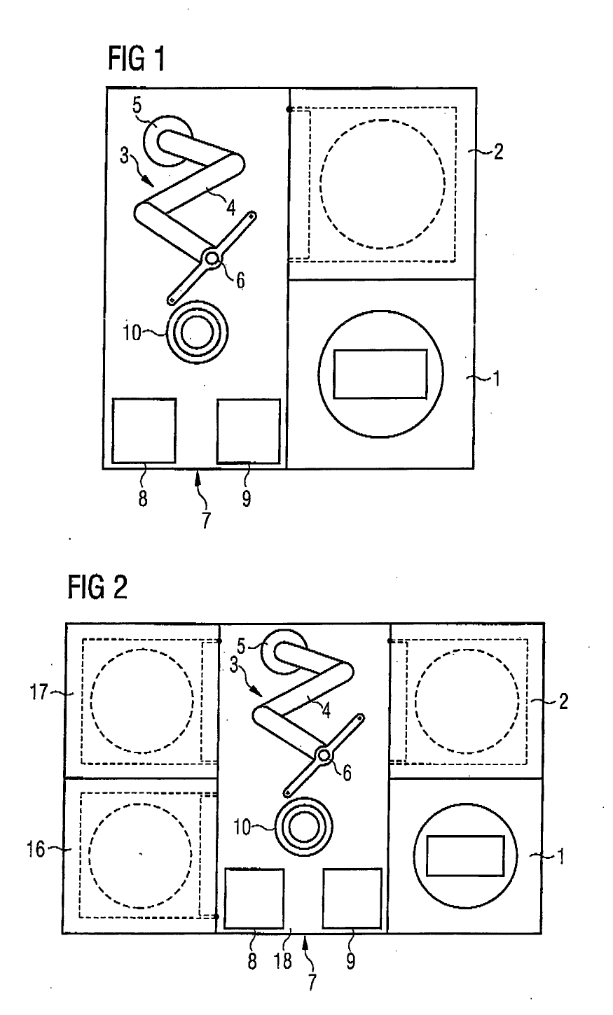

A listing of the reference characters and the corresponding elements shown in FIGS. 1-4 is provided below:

1 First prober

2 First temperature control station

3 Handling system

4 Robot arm

5 Robot drive

6 Wafer holder

7 Wafer magazine station

8 Input wafer magazine

9 Output wafer magazine

10 Alignment station

11 Front side

12 Door

13 Heating chamber

14 Semiconductor wafer

15 Inert gas connection

16 Second temperature control station

17 Third temperature control station

18 Central free space

19 Fourth temperature control station

20 Second prober

21 Expansion module

22 Housing

23 Housing door

24 Operator gangway

25 Free region

### DESCRIPTION OF THE INVENTION

As FIG. 1 illustrates, a first prober 1 and a first temperature control station 2 are provided, which are in each case of modular structure such that their external dimensions are subject to the same grid dimension and, in the present exemplary embodiment, are equal to one another. This makes it possible to place the module of the prober 1 and the module of the first temperature control station 2 close beside each other and to connect them to each other.

Arranged laterally beside the row comprising first prober 1 and first temperature control station 2 is a handling system 3. The handling system 3 includes a robot arm 4 which is attached to a robot drive 5. Arranged on the free front side of the robot arm 4 is a wafer holder 6, by means of which an underside of a semiconductor wafer, not specifically illustrated, can be picked up and attracted by suction by means of a vacuum.

Also provided is a wafer magazine station 7, into which an input wafer magazine 8 and an output wafer magazine 9 can be inserted.

An alignment station 10 is provided between the wafer magazine station 7 and the handling system 3.

The first temperature control station has on its front side 11 a door 12 which closes a heating chamber 13 tightly. Provided in the heating chamber 13, one above another, are compartments, not specifically illustrated, in which semiconductor wafers 14 can be stacked one above another. The heating chamber 13 is provided with an inert gas connection 15.

The function of the apparatus is now to be seen in that, by means of the wafer holder 6, a semiconductor wafer is removed from the input wafer magazine 8 and inserted into the first temperature control station 2 with the door 12 opened. In this way, the temperature control station 2 can be filled.

Once the latter has been filled with a stack of semiconductor wafers 14, the door 12 is closed and inert gas is let into the heating chamber via the inert gas connection 15, by which means oxidation processes as a result of the action of heat on the semiconductor wafers 14 can be avoided. In this case, however, there is also the possibility that another gas is let in via the inert gas connection 15, with which for example a chemical or another physical loading is implemented.

The heating chamber 13 is then brought to a temperature which represents a loading of the semiconductor wafers 14, via heating elements that are not specifically illustrated. At the same time, a temperature profile over time is maintained via control devices, likewise not specifically illustrated.

For the purpose of testing, following a loading time in which the semiconductor wafer 14 was subjected to heat, the semiconductor wafer 14 is then deposited temporarily on the alignment station 10. In this alignment station 10, the position of the semiconductor wafer is adjusted, in order that the latter has a correct positional orientation when inserted into the prober 1 and only needs to be adjusted precisely in the prober 1 during testing. Then, under the control of the robot arm 4 and the robot drive, the semiconductor wafer 14 is optionally transferred back into the first temperature control station 2, if only intermediate testing is carried out, or into the output wafer magazine 9, if the loading test or a bum in has been completed. Which of the possibilities is selected is determined by a control program.

As FIG. 2 illustrates, a second temperature control station 16 and a third temperature control station 17 are provided, which are arranged symmetrically with respect to the centre of the apparatus. Therefore, the handling system 3, the alignment station 10 and the wafer magazine station 7 are in the central free space 18 in the apparatus which is visible in the plan view.

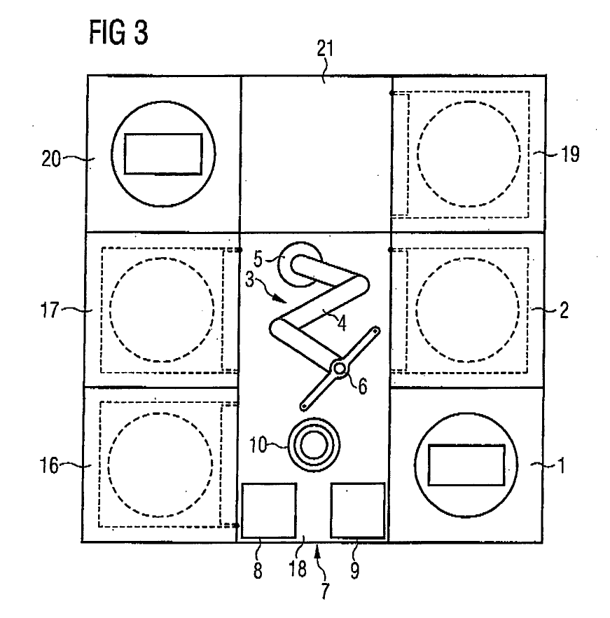

As FIG. 3 illustrates, a fourth temperature control station 19 and a second prober 20 are provided. All the modules 1, 2, 16, 17, 19 and 20 are in this case arranged in such a way that the central free space 18 remains available for the arrangement of the handling system 3 and the alignment station 10.

In this arrangement, space is also provided for an expansion module 21, where, optionally, another testing station or another module, for example a temporary storage module or a second wafer magazine station, can be arranged.

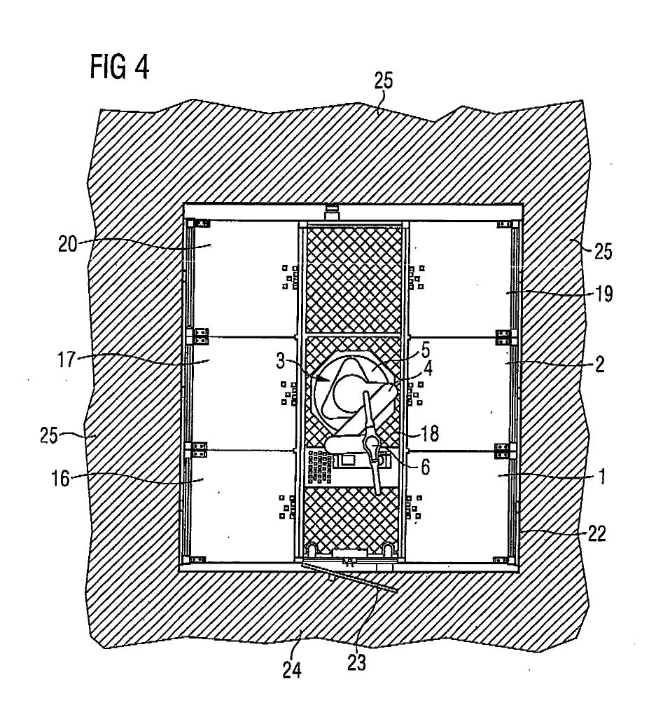

FIG. 4 illustrates an apparatus having probers 1 and 20 and having temperature control stations 2, 16, 17, 19 and 20. The entire apparatus has a common housing 22 which is provided with a housing door 23 only on the side of the wafer magazine station 7. Through this housing door, the wafer magazines 8 and 9, which are not specifically illustrated in FIG. 4, can be operated. An operator gangway 24 is provided only for this operation. The other free regions 25 are not necessary, so that the space required, which is small in any case, could be reduced still further.

Depending on the application and area of use, all the probers 1 and 20 can implement the same or different functions, such as the testing and temperature influence high speed testing, highly accurate testing or testing under special environmental conditions, and the temperature control stations 2, 16, 17, 19 and 20 can implement the same or different loading programs.

1. An arrangement for testing a substrate under load, the arrangement having a prober and comprising a chuck, chuck drive, control electronics, probe or probe card holding means, and having loading means for applying any one of a thermal, mechanical, electrical and other physical or chemical loading to the substrate, the arrangement characterized in that the loading means is arranged as a separate subassembly separated from the prober and therein is connected to the latter via a handling system.

2. The arrangement according to claim 1 further comprising an alignment station for the defined alignment of the substrate.

3. The arrangement according to claim 1 further comprising a substrate magazine station.

4. The arrangement according to claim 1 wherein the loading means comprises a temperature control station.

5. The arrangement according to claim 4 wherein the temperature control station comprises a temperature control chamber in which holding means for a plurality of substrates is disposed.

6. The arrangement according to claim 5 wherein the temperature control chamber is closable in a substantially gastight manner and is connectable to an inert gas source.

7. The arrangement according to claim 1 further comprising a common housing, wherein the prober or probers, the loading means, and the handling system are disposed.

8. The arrangement according to claim 7 wherein a substrate magazine station and an alignment station are disposed in the common housing.

9. The arrangement according to claim 1 wherein the prober and the loading means are each arranged in a module.

10. The arrangement according to claim 9 wherein each module has the same basic grid dimensions and each module is connectable to other modules.

11. The arrangement according to claim 9 wherein at least a module is mobile and is designed to be locked in its erected position.

12. The arrangement according to claim 9 wherein at least one of the loading means and the prober are provided repeatedly and are operatively connected to one another via a same handling system.

13. The arrangement according to claim 9 wherein each module is arranged on a vibration-insulating, preferably position-controlled, platform.

14. The arrangement according to claim 9 characterized in that each module is arranged on a separate platform from the other modules.

15. The arrangement according to claim 9, wherein the modules are arranged to form a central free space in the plan view, and at least one of the handling system and the alignment station are disposed in the central free space.

16. The arrangement according to claim 1 further characterized in that it is designed to test semiconductor wafers substrates.

17. A method of testing a substrate under load, the substrate being subjected to a thermal, mechanical, electrical or another physical or chemical loading and the properties of the same being measured by means of a prober, the method comprising:
bringing the substrate into operative connection with a loading means;
subjecting the substrate to a loading in the loading means;
then removing the substrate from the loading means; and
testing the substrate functions.

18. The method according to claim 17 wherein subjecting the substrate to a loading comprises executing a loading program in which the loading variables vary during a loading time period.

19. The method according to claim 17 wherein during a loading time period, the substrate is repeatedly removed from the loading means and tested at time intervals during the loading time period.
